(19) United States
(12) Patent Application Publication
(10) Pub. No.: US 2017/0084523 A1
(43) Pub. Date: Mar. 23, 2017

(54) ON-PACKAGE CONNECTOR

(71) Applicant: QUALCOMM Incorporated, San Diego, CA (US)

(72) Inventors: Jie FU, San Diego, CA (US); Daeik Daniel KIM, Del Mar, CA (US); Manuel ALDRETE, Encinitas, CA (US); Chin-Kwan KIM, San Diego, CA (US); David BERDY, San Diego, CA (US); Niranjan Sunil MUDAKATTE, San Diego, CA (US); Changhan YUN, San Diego, CA (US); Je-Hsiung LAN, San Diego, CA (US); Jonghae KIM, San Diego, CA (US)

(21) Appl. No.: 14/861,619

(22) Filed: Sep. 22, 2015

(51) Int. Cl. H01L 23/498; H01L 23/00; H01L 21/78; H01L 21/56; H01L 23/538; H01L 23/31

(52) U.S. Cl. CPC H01L 23/49805; H01L 23/49838; H01L 23/5389; H01L 23/3121; H01L 21/78; H01L 21/565; H01L 21/561; H01L 24/97; H01L 23/49833; H01L 24/17; H01L 2224/16225

(57) ABSTRACT

Conventional ways of coupling die packages to external devices include providing contacts on a separate area on a printed circuit board (PCB). These PCB contacts are configured to mate with connector contacts of a connector to enable coupling with external devices. Unfortunately, the PCB contacts take up significant amount of area of the PCB. Also, the connection can suffer from parasitic losses and signal integrity can be compromised. An on-package connection is proposed to address the short comings of the conventional ways. The on-package connection enables a die package to connect directly with the connector. This removes the need to provide a separate area for PCB contacts. Also, parasitic losses are minimized and signal integrity is enhanced.

### FIELD OF DISCLOSURE

One or more aspects of the present disclosure generally relate to semiconductor device packaging, and in particular, to an on-package connector such as in a flip chip (FC) module or in other wafer level packages that saves space, e.g., on a printed circuit board (PCB) and increases signal integrity.

### BACKGROUND

Mobile electronics have many connectors between components and boards. Examples include multiple RF antennas, LCD, digitizer, power supply, camera (front and back), and sensors among others. The connectors typically take up large amount of PCB area and volume, and do not scale readily. The connectors, which are electrically driven by active components, also suffer from parasitic losses and the signal integrity can be compromised. Further, connectors and cables are often too bulky.

FIG. 1 illustrates an example of a conventional module 100 such as a FC module. The conventional module 100 includes a die package 110 and a connector 180. In this example, the die package 110 includes a die 120 with die bumps 125 on a substrate 130 with substrate bumps 135 mounted on a PCB 170. The connector 180 includes a cable 190 and connector contacts 185. The module 100 also includes PCB contacts 175.

While not explicitly shown, it may be assumed that the die bumps 125 are electrically coupled to inputs and/or outputs of the die 120. It may also be assumed that there are interconnectors within the substrate 130 to route signals between the die bumps 125 and the solder bumps 135. It may further be assumed that there are interconnectors within the PCB 170 to route signals between the solder bumps 135 and the PCB contacts 185, which mate with the connector contacts 185 of the connector 180.

The connector 180 is used to provide connection between the die package 110 and external components. In the figure, an example electrical coupling, i.e., a signal path between the die 120 and the connector 180 is illustrated as a heavy dashed line. Note that the signal path between die 120 and the connector 180 can be lengthy since the signal traverses the PCB 170. Also, it is common that the PCB contacts 175 occupy a separate area of the PCB 170.

### SUMMARY

This summary identifies features of some example aspects, and is not an exclusive or exhaustive description of the disclosed subject matter. Whether features or aspects are included in, or omitted from this Summary is not intended as indicative of relative importance of such features. Additional features and aspects are described, and will become apparent to persons skilled in the art upon reading the following detailed description and viewing the drawings that form a part thereof.

An exemplary die package is disclosed. The die package may comprise a die coupled to a substrate. The die package may also comprise a plurality of package contacts on an outer perimeter of the die package. The plurality of package contacts may be configured to mate with a connector. The die may be configured to electrically couple to the connector through a plurality of connector contacts if the plurality of package contacts are mated with the plurality of connector contacts.

An exemplary method to form a die package is disclosed. The method may comprise coupling a die to a substrate. The method may also comprise forming a plurality of package contacts on an outer perimeter of the die package for mating with a connector and for electrically coupling to the connector through a plurality of connector contacts if the plurality of package contacts are mated with the plurality of connector contacts.

### BRIEF DESCRIPTION OF THE DRAWINGS

The accompanying drawings are presented to aid in the description of embodiments disclosed and are provided to show illustrations of the embodiments and not limitation thereof.

FIG. 1 illustrates a conventional flip chip (FC) module;

FIG. 2A illustrates an example embodiment of a die package;

FIG. 2B illustrates an example embodiment of a die package mated with a connector;

FIG. 3A illustrates a top view of a die package of FIG. 2A;

FIG. 3B illustrates a top view of a die package mated with a connector;

FIG. 4 illustrates another example embodiment of a die package;

FIGS. 5A and 5B illustrate top views of a die package of FIG. 4;

FIG. 6 illustrates a flow chart of an example method to form a die package;

FIG. 7 illustrates a flow chart of an example process to form package contacts of a die package;

FIGS. 8A-8C illustrate different stages of a process to form a die package of FIG. 2A;

FIG. 8D illustrates a top view of a stage of forming a die package of FIG. 2A;

FIGS. 9A-9D illustrate different stages of another process of forming a die package FIG. 4;

FIG. 9E illustrates a top view of a stage of forming a die package FIG. 4;

FIGS. 10A-10D illustrate different stages of another process of forming a die package of FIG. 4;

FIG. 10E illustrates another top view of a stage of forming a die package of FIG. 4; and

FIG. 11 illustrates a flow chart of an example method to form a die package.

### DETAILED DESCRIPTION

Aspects are disclosed in the following description and related drawings directed to specific embodiments of one or more aspects of the present disclosure. Alternate embodiments may be devised without departing from the scope of the discussion. Additionally, well-known elements will not be described in detail or will be omitted so as not to obscure the relevant details.

The word “exemplary” is used herein to mean “serving as an example, instance, or illustration.” Any embodiment described herein as “exemplary” is not necessarily to be construed as preferred or advantageous over other embodiments. Likewise, the term “embodiments” does not require that all embodiments of the disclosed subject matter include the discussed feature, advantage or mode of operation.

The terminology used herein is for the purpose of describing particular embodiments only and is not intended to be limiting. As used herein, the singular forms “a”, “an” and “the” are intended to include the plural forms as well, unless the context clearly indicates otherwise. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

Further, many embodiments are described in terms of sequences of actions to be performed by, for example, elements of a computing device. It will be recognized that various actions described herein can be performed by specific circuits (e.g., application specific integrated circuits (ASICs)), by program instructions being executed by one or more processors, or by a combination of both. Additionally, these sequence of actions described herein can be considered to be embodied entirely within any form of computer readable storage medium having stored therein a corresponding set of computer instructions that upon execution would cause an associated processor to perform the functionality described herein. Thus, the various aspects may be embodied in a number of different forms, all of which have been contemplated to be within the scope of the claimed subject matter. In addition, for each of the embodiments described herein, the corresponding form of any such embodiments may be described herein as, for example, “logic configured to” perform the described action.

As indicated above, electronic have many connectors between components and boards. Examples include multiple RF antennas, LCD, digitizer, power supply, camera (front and back), and sensors among others. In one or more aspects of the present disclosure, an on-package connection may be provided. Some advantages of the present disclosure include those below, but is not so limited
Reducing on-board connector area and electrical wiring parasitics;
Utilizing the die package as a connector;
Saving board area, routing, and logic board volume;
Increasing signal integrity;
Plating on molding can implement sidewall and top metallization; and
Shielding can be implemented together.

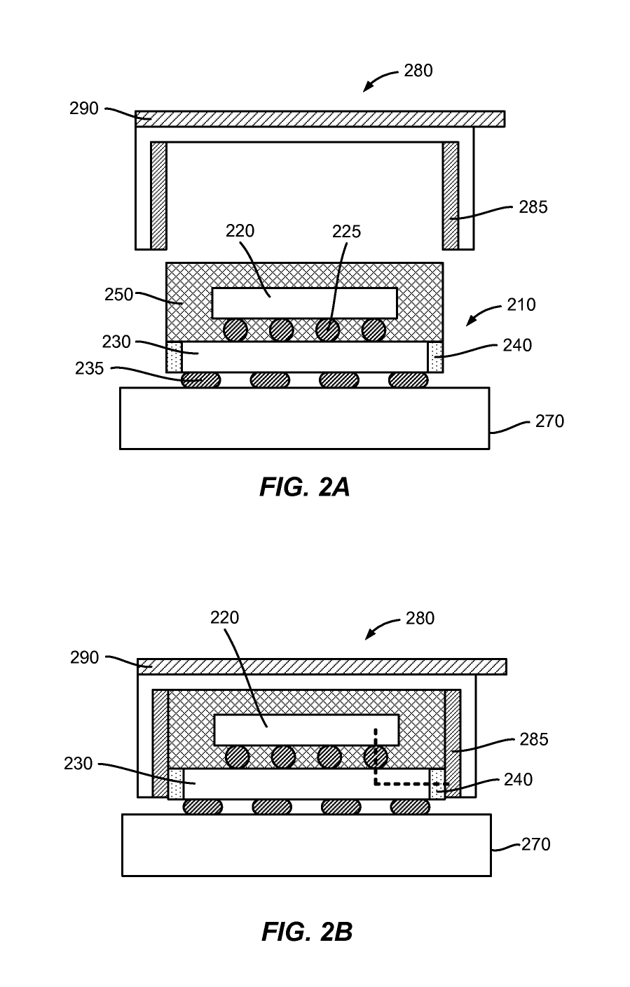

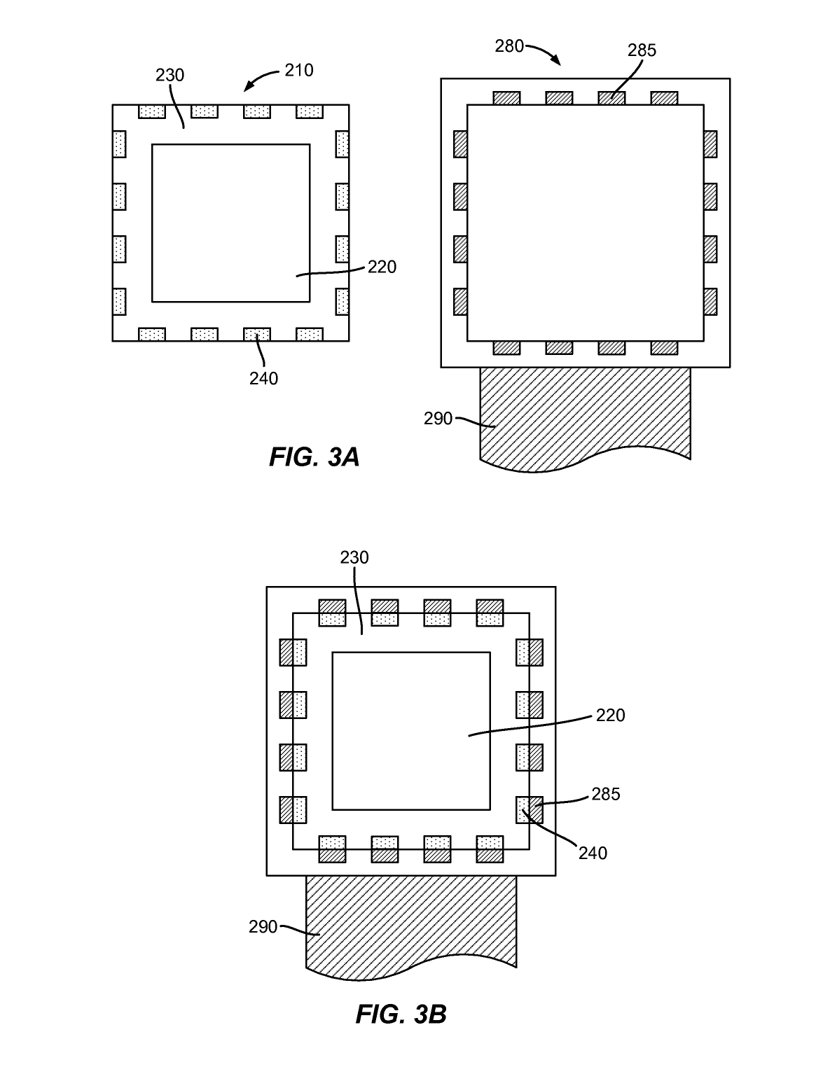

FIGS. 2A, 2B, 3A and 3B illustrate an example embodiment of a die package 210. FIG. 2A illustrates a side view of the die package 210 separated from a connector 280. So as to minimize clutter, not all element labels are repeated in FIG. 2B. FIG. 3A illustrates a top view of the die package 210 and FIG. 3B illustrates a top view of the die package 210 mated with the connector 280. Again so as to minimize clutter, a mold 250 and a mounting board 270 (explained below) are not shown in FIGS. 3A and 3B. In an aspect, a plurality of package contacts may be formed on an outer perimeter of the die package 210 and configured to mate with the connector 280. For example, as seen in these figures, the die package 210 may comprise a die 220 coupled to a substrate 230. The die package 210 may also comprise a plurality of first contacts 240 on an outer perimeter of the substrate 230. The die 220 and the plurality of first contacts 240 may be electrically coupled through the substrate 230. That is, the inputs and/or outputs (e.g., data and power inputs and/or outputs) of the die 220 may be electrically coupled with the plurality of first contacts 240 through a plurality of interconnects within the substrate 230 (not shown). For example, the plurality of first contacts 240 may be provided as contact pads within the substrate 230.

Note that an on-package connection can be provided. That is, the die package 210 may be connected directly to the connector 280 as seen in FIGS. 2B and 3B. In particular, the plurality of first contacts 240 of the die package 210 may be configured to mate with the plurality of connector contacts 285 of the connector 280. When mated, the die 220 may be electrically coupled to the connector 280 through interconnects (not shown) in the substrate 230, through the plurality of first contacts 240 and through the plurality of connector contacts 285. Recall that the plurality of package contacts may be on the outer perimeter of the die package 210. For example, the plurality of first contacts 240 may be formed on the outer perimeter of the substrate 230.

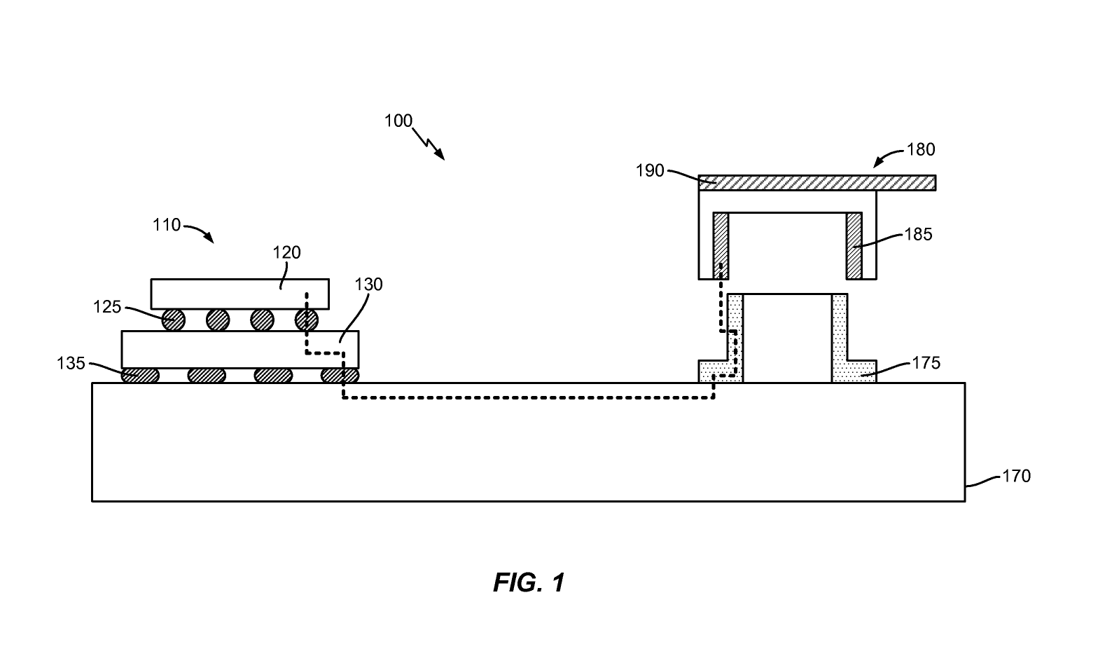

The on-package connection provided by the die package 210 example as illustrated in FIG. 2B allows a direct coupling between the die package 210 and the connector 280 when the plurality of connector contacts 285 are mated with the connector 280, e.g. with the plurality of first contacts 240. When mated, the die 220 may be electrically coupled to the connector 280 other than through a PCB, i.e., the PCB is not required for a signal path between the die 220 and the connector 280. This is unlike the conventional FC module 100 of FIG. 1 in which the electrical coupling between the die package 110 and the connector 180 is provided through the PCB 170. Note that the heavy dashed line in FIG. 2B is much shorter than the corresponding line in FIG. 1. This visually demonstrates that the coupling of the die package 210 and the connector 280 allowed through the on-package connection can shorten the signal path between the die 220 and the connector 280 considerably. This reduces the parasitic losses, which in turn leads to greater signal integrity. Electrical coupling of the die 220 to external components may be provided through the cable 290 of the connector 280.

Continuing with FIG. 2A, the die package 210 may be provided with a mounting board 270. When provided, the substrate 230 may be mounted on the mounting board 270. A PCB may be an example of a mounting board 270. It should be realized that for on-package connection purposes, the mounting board 270 may be optional. However, the mounting board 270 can be advantageous in that physical stability and/or durability can be enhanced. Also, while not shown, multiple die packages 210 may be mounted on a PCB for example. When the multiple die packages 210 are mounted on the PCB, electrical couplings among the die packages 210 may be provided through the PCB.

The die package 210 may further comprise a mold 250 formed over the substrate 230. The mold 250 may be formed so as to at least partially surround the die 220. The mold 250 is optional for the on-package connection. When included, the mold 250 can provide a measure of protection for the die 220.

As indicated above, FIGS. 2A and 2B respectively illustrate side views of the die package 210 and the connector 280 before and after the two are mated. For example, as seen in FIG. 2B, the plurality of first contacts 240 may be mated with the plurality of the connector contacts 285. FIG. 3A and 3B also illustrate views before and after mating, but from the top. FIG. 3B illustrates more clearly the mating that may occur between the plurality of first contacts 240 and the connector contacts 285. Electrical connections with external components (not shown) may be provided through the cable 290.

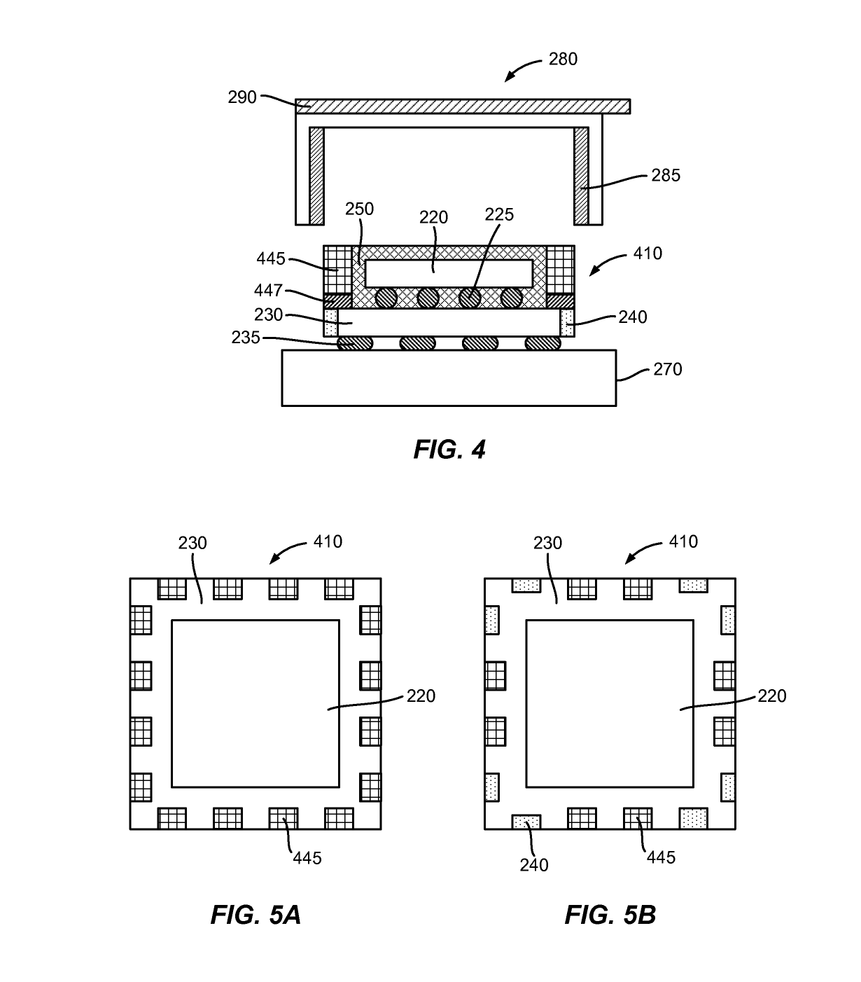

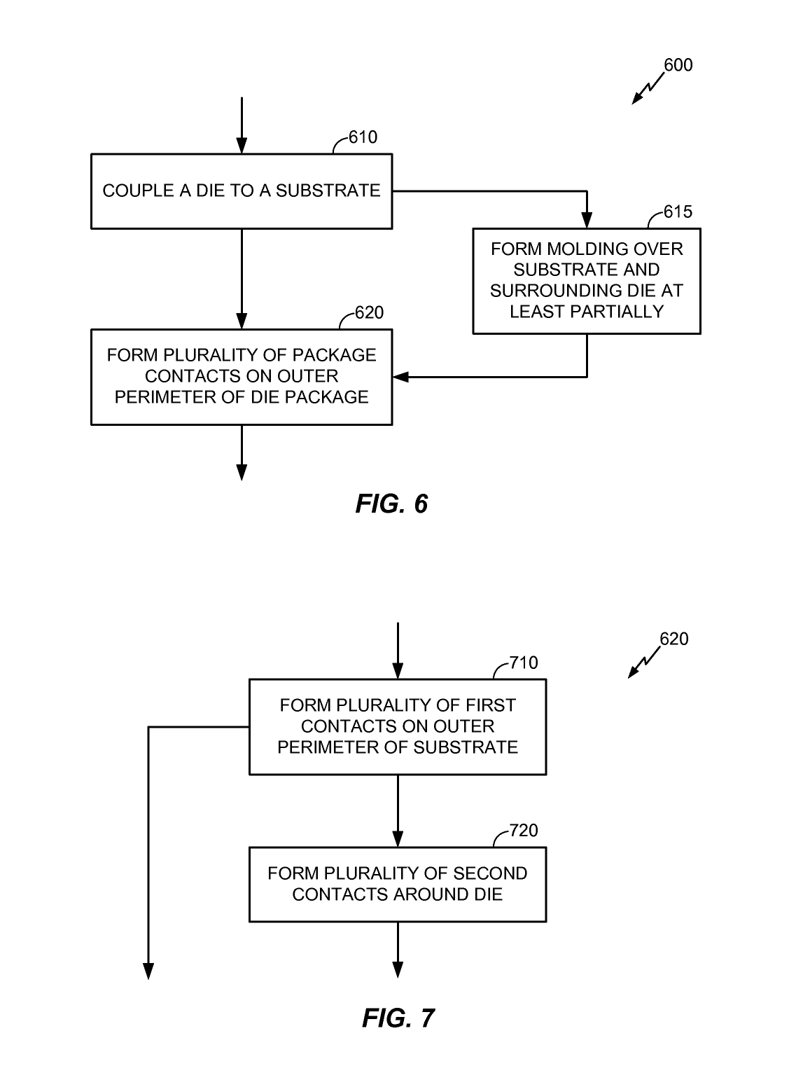

FIG. 4 illustrates a side view of another example embodiment of a die package 410. FIG. 4 illustrates the die package 410 separated from the connector 280, i.e., in an unmated state similar to FIG. 2A. FIGS. 5A and 5B may also be said to illustrate top views of the die package (again with the mold 250 and the mounting board 270 omitted to minimize clutter). For the remainder of the figures, only the unmated views are provided. However, visualizing the mated forms is relatively straight forward and are fully contemplated.

The die package 410 of FIG. 4 includes many of the same or similar elements as the die package 210 illustrated in FIG. 2A. For example, the die package 410 may comprise a die 220 coupled to a substrate 230, and a plurality of first contacts 240 may be on an outer perimeter of the substrate 230. Also, the die 220 and the plurality of first contacts 240 may be electrically coupled through the substrate 230.

But in addition, the die package 410 may comprise a plurality of second contacts (e.g. package contacts) 445 disposed around the die 220. The plurality of second contacts 445 may be electrically coupled to the plurality of first contacts 240. In this way, the die 220 may be electrically coupled to the plurality of second contacts 445. In one aspect, the plurality of second contacts 445 may be configured to mate with the plurality of connector contacts 285. It can be said that the plurality of second contacts 445 may be formed on an outer perimeter of the die package 410. In an example not shown, the plurality of second contacts 445 may be formed on the plurality of first contacts 240, which are formed on the outer perimeter of the substrate 230.

The die package 410 may optionally comprise a plurality of intermediate contacts 447 which provide electrical connectivity between the plurality of first and second contacts 240, 445. For example, the plurality of intermediate contacts 447 may be solder contacts.

In one aspect, all of the first contacts 240 may be electrically coupled to all of the second contacts 445. This is illustrated in FIG. 5A. Note only the second contacts 445 are visible from the top. In another aspect, there can be one or more second contacts 445 that are not coupled to any of the first contacts 240. In the aspect described above, it is sufficient that at least some of the second contacts 445 be electrically coupled to at least some of the first contacts 240. In this way, when the plurality of second contacts 445 are mated with the plurality of connector contacts 285, there are electrical couplings between the die 220 and the connector 280.

In another aspect, the plurality of first contacts 240 may also be configured to mate with the plurality of connector contacts 285. In this aspect, the plurality of package contacts may comprise the plurality of first contacts 240 as well as the plurality of second contacts 445. Even in this aspect, it may be said that the plurality of package contacts may be formed on the outer perimeter of package 410. For example, note that the plurality of first contacts 240 may be formed on the outer perimeter of the substrate 230. Alternatively or in addition thereto, the plurality of second contacts 445 may be formed to at least partially surround the die 220. There can be some variations to this aspect, which may include any one or more of the following:
At least one connector contact 285 mates with both corresponding first and second contacts 240, 445;
At least one connector contact 285 mates with the corresponding first contact 240 only; and
At least one connector contact 285 mates with the corresponding second contact 445 only.

Similar to the die package 210 of FIG. 2A, the die package 410 of FIG. 4 may be provided with a mounting board 270 such as a PCB. Recall that the mounting board 270 is optional for on-package connection purposes, but can be provided for other reasons such as for physical attributes and/or to enable electrical couplings among multiple die packages 410. The die package 410 may include a mold 250 formed on the substrate 230 surrounding the die 220. Again, the mold 250 may be optional. When provided, the plurality of second contacts 445 may be disposed on an outer perimeter of the mold 250.

Note that in both FIGS. 2 and 4, the connector 280 is illustrated to be removable as well as being separate from the mounting board 270. While not shown, it is contemplated that in some embodiments, the connector 280 may be fixedly mated with the plurality of package contacts (e.g., with the plurality of first contacts 240 and/or the plurality of second contacts 445). Also, sides of the plurality of package contacts 240, 445 may mate with the plurality of connector contacts 285.

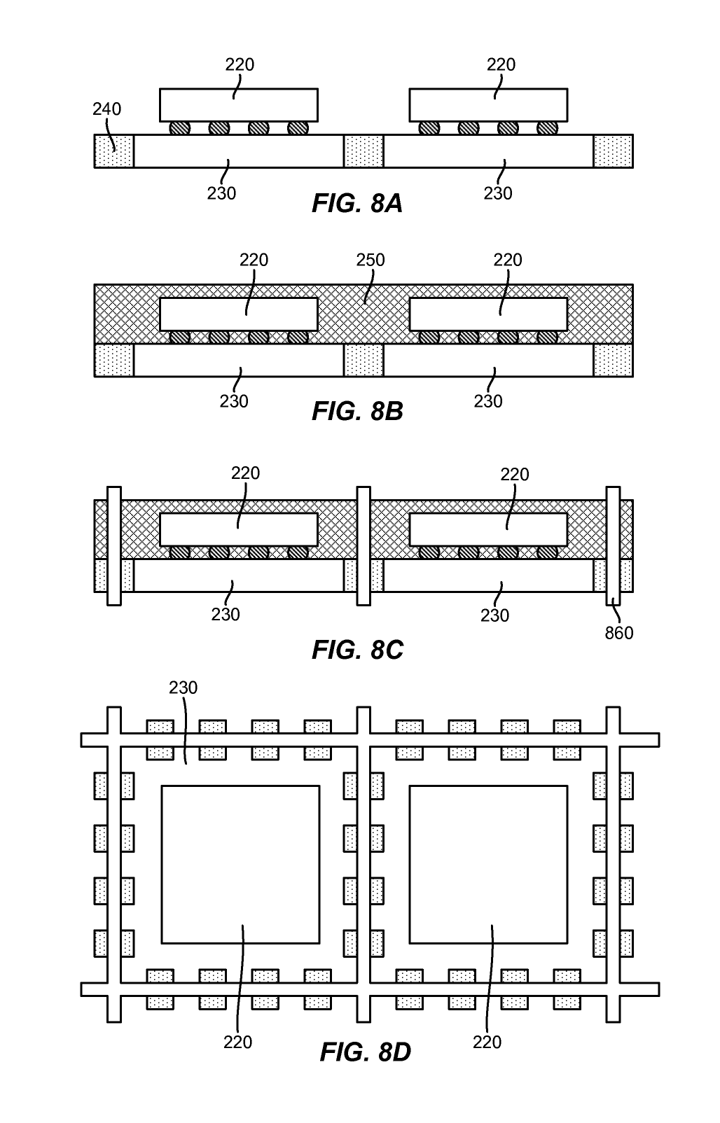

FIG. 6 illustrates a flow chart of an example method 600 to form a die package 210, 410. The method 600 may include coupling a die 220 to a substrate 230 (block 610). The substrate 230 may or may not be mounted on a mounting board 270 such as a PCB. The example method 600 may also include forming a plurality of package contacts, e.g., forming a plurality of first and/or second contacts 240, 445 (block 620). The plurality of first and/or second contacts 240, 445, e.g., the plurality of package contacts, are formed so as to be on an outer perimeter of the die package 210. The die 220 is configured to be electrically coupled to a connector 280 through the plurality of first and/or second contacts 240, 445 and through a plurality of connector contacts 285 when the plurality of first and/or second contacts 240, 445 are mated with the plurality of connector contacts 285.

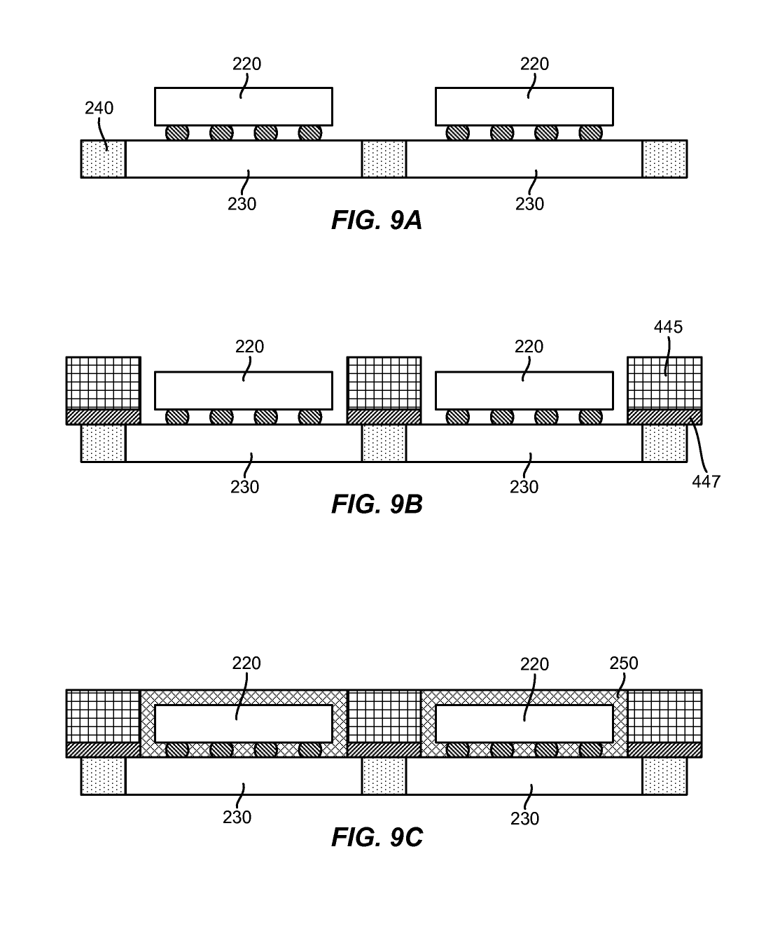

FIG. 7 illustrates a flow chart of an example of the process 620 to form the plurality of first and/or second contacts 240, 445 (e.g. package contacts). The example process 620 includes forming a plurality of first contacts 240 (block 710). The plurality of first contacts 240 are formed so as to be on the outer perimeter of the substrate 230. The plurality of first contacts 240 are electrically coupled to the die 220 through the substrate 230. In an aspect, the plurality of first contacts 240 are configured to mate with the plurality of connector contacts 285. This aspect corresponds to forming the die package 210 embodiment illustrated in FIG. 2A, i.e., the plurality of package contacts comprises the plurality of first contacts 240. In an aspect, this is sufficient to electrically couple the die 220 and the connector 280, and the process 620 need not go further as seen by an arrow exiting the block 710 on the left.

But in an alternative, the process 620 also comprises forming a plurality of second contacts 445 around the die 220 (block 720). The plurality of second contacts 445 are electrically coupled to the plurality of first contacts 240 which are in turn electrically coupled to the die 220 through the substrate 230. In an aspect, the plurality of second contacts 445 are configured to mate with the plurality of connector contacts 285. This aspect corresponds to forming the die package 410 embodiment illustrated in FIG. 4, i.e., the plurality of package contacts comprises the plurality of second contacts 445. While not shown, the alternative process 620 may include forming a plurality of intermediate contacts 447. In a variation, the plurality of package contacts comprises the plurality of first contacts 240 in addition to the plurality of second contacts 445.

Referring back to FIG. 6, the method 600 optionally comprises forming a mold 250 on or over the substrate 230 (block 615). The mold 250 is formed so as to at least partially surround the die 220. When the plurality of second contacts 445 are formed, the plurality of second contacts 445 are disposed on an outer perimeter of the mold 250.

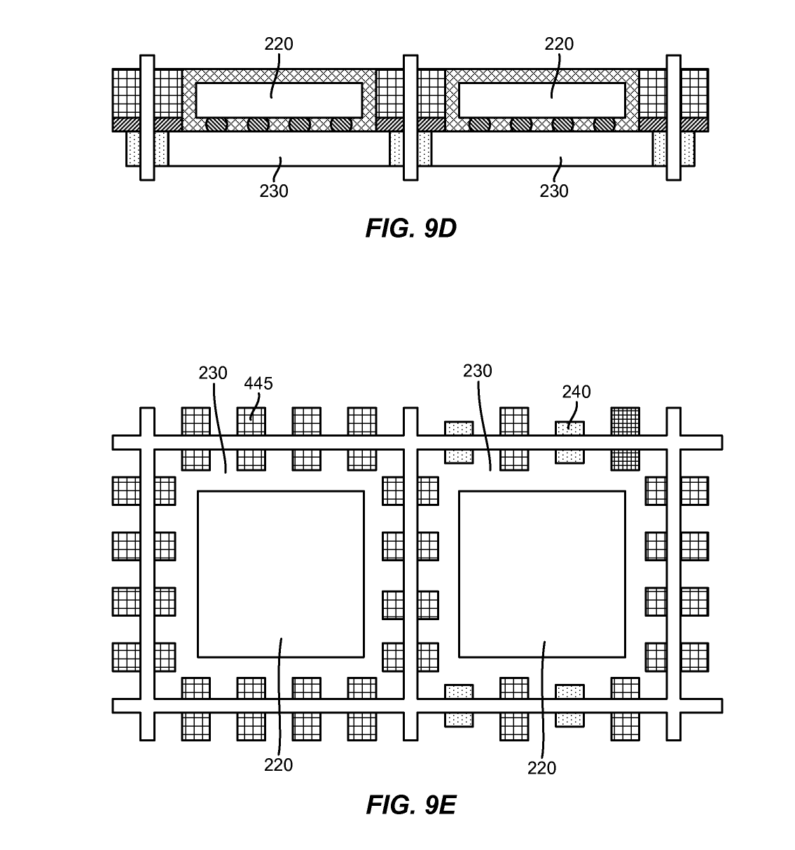

FIGS. 8A-8C illustrate different stages of an example process to form a die package such as the die package 210 of FIG. 2A. In FIGS. 8A-8C, a plurality of substrates 230 and a plurality of first contacts 240 formed on the perimeters of the substrates 230 are illustrated. FIG. 8A illustrates a stage in which multiple dies 220 are attached to their corresponding substrates 230. After the attachment, each die 220 is electrically coupled to the plurality of first contacts 240 on the perimeter of the corresponding substrate 230.

FIG. 8B illustrates a stage in which a mold 250 is formed on or over the dies 220, the substrates 230 and the plurality of first contacts 240. The mold 250 is formed so as to at least partially surround the dies 220. Note that the mold 250 is optional. So the process illustrated in this figure need not be performed.

FIG. 8C illustrates a stage in which the plurality of substrates 230 are diced along dicing boundaries 860. The dicing is performed so as to separate the substrates 230 from one another. As seen, the plurality of first contacts 240 are also diced. In this way, after the dicing, individual die packages, such as the die packages 210 of FIG. 2A, are formed. In FIG. 8C, it is assumed that the optional process of forming the mold 250 has been performed. But of course, even if the mold 250 is not formed, the dicing stage of FIG. 8C is still valid.

FIG. 8C illustrates a side view of the dicing stage. FIG. 8D illustrates a top view of the substrates 230 with the dicing boundaries 860 (mold 250 not shown). It is easy to visualize that after the dicing, the die package 210 of FIG. 3 (top view illustration) are formed.

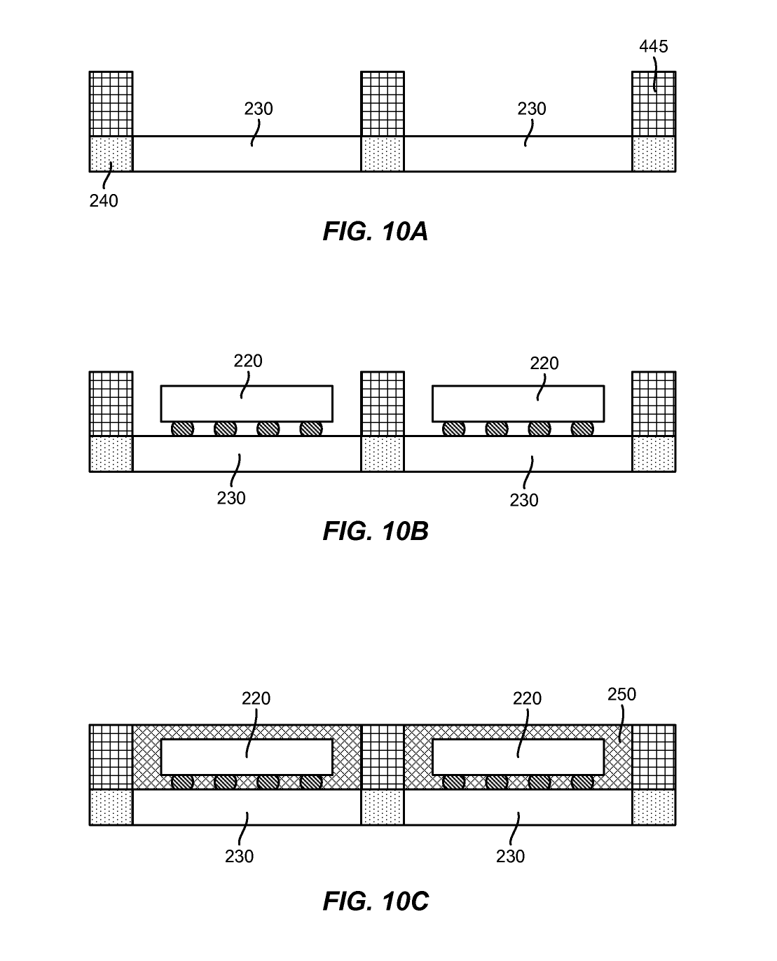

FIGS. 9A-9D illustrate different stages of an example process to form a die package such as the die package 410 of FIG. 4. Similar to FIGS. 8A-8C, a plurality of substrates 230 and a plurality of first contacts 240 are formed on the perimeters of the substrates. FIG. 9A illustrates a stage in which the dies 220 are attached to their corresponding substrates 230 much like FIG. 8A. After the attachment, each die 220 is electrically coupled to the plurality of first contacts 240 on the perimeter of the corresponding substrate 230.

FIG. 9B illustrates a stage in which a plurality of second contacts 445 are formed around the dies 220 and electrically coupled to the plurality of first contacts 240. In this figure, the plurality of second contacts 445 are shown to be electrically coupled to the plurality of first contacts 240 through a plurality of intermediate contacts 447. For example, the plurality of second contacts 445 and the plurality of intermediate contacts 447 (e.g., solder) may be surface mounted on the plurality of first contacts 240 followed by a reflow process. But as mentioned previously, the plurality of intermediate contacts 447 are optional.

FIG. 9C illustrates a stage in which the mold 250 is formed on the dies 220, the substrates 230 and the plurality of first contacts 240. The mold 250 is formed to at least partially surround the dies 220. Again, the mold 250 is optional.

FIG. 9D illustrates a stage in which the multiple substrates 230 are diced along dicing boundaries 860 to separate the substrates 230 from one another. In this instance, the plurality of first contacts 240 and the plurality of second contacts 445 are also diced. In this way, after the dicing, individual die packages, such as the die packages 410 of FIG. 4, are formed. In FIG. 9D, it is assumed that the optional process of forming the mold 250 has been performed. Nonetheless, even if the mold 250 is not formed, the dicing stage of FIG. 9D is still valid.

FIG. 9D illustrates a side view of the dicing stage. FIG. 9E illustrates a top view of the substrates 230 with the dicing boundaries 860 (mold 250 not shown). It is easy to visualize that after the dicing, the die packages 410 of FIGS. 5A and 5B (top view illustrations) may be formed.

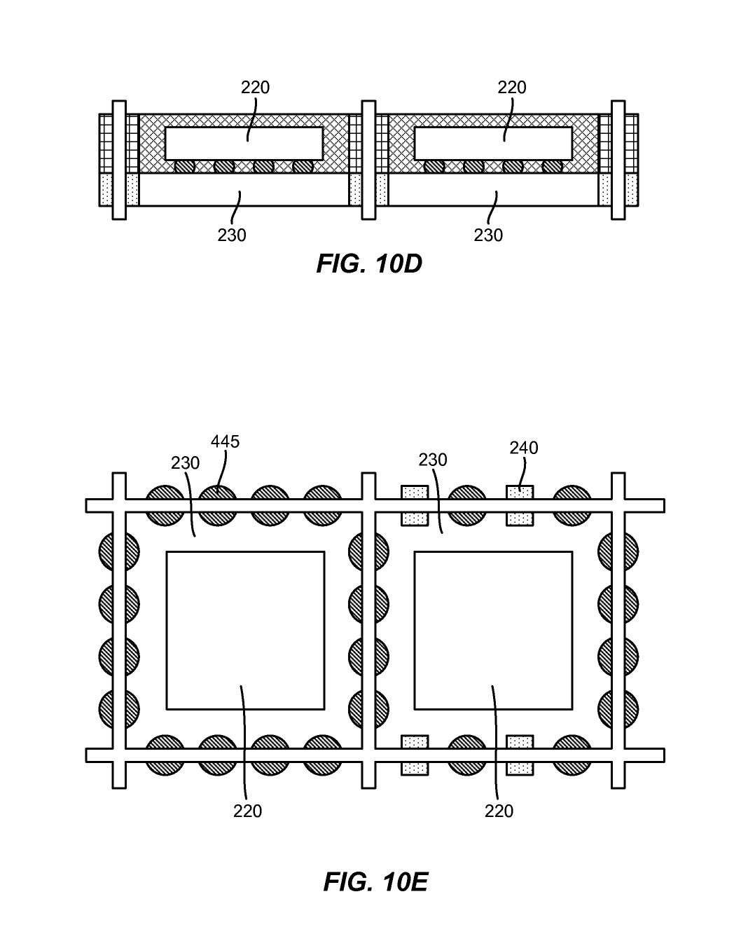

FIGS. 10A-10D illustrate different stages of another example process to form a die package such as the die package 410 of FIG. 4. FIG. 10A illustrates a stage in which a plurality of second contacts 445 are formed. As seen, the plurality of second contacts 445 are formed so as to be electrically coupled to the plurality of first contacts 240. In this figure, the plurality of second contacts 445 are shown to be electrically coupled to the plurality of first contacts 240 directly. For example, the plurality of second contacts 445 may be formed through a copper (Cu) post plating process.

FIG. 10B illustrates a stage in which the dies 220 are attached to the corresponding substrates 230. Note that the dies 220 are attached such that the plurality of second contacts 445 are disposed around the dies 220. In this figure, the plurality of second contacts 445 are shown to be electrically coupled to the plurality of first contacts 240 directly. Unlike FIGS. 9A-9B, this alternative process in FIGS. 10A and 10B attaches the die 220 after the second contacts 445 are formed.

FIG. 10C illustrates a stage in which the mold 250 is formed on the dies 220, the substrates 230 and the plurality of first contacts 240. The mold 250 is formed so as to at least partially surround the dies 220. Again, the mold 250 is optional.

FIG. 10D illustrates a stage in which the substrates 230 are diced along dicing boundaries 860 to separate the substrates 230 from one another. The plurality of first contacts 240 and the plurality of second contacts 445 are also diced. In this way, after the dicing, individual die packages, such as the die packages 410 of FIG. 4, are formed. In FIG. 10D, it is assumed that the optional process of forming the mold 250 has been performed. Nonetheless, even if the mold 250 is not formed, the dicing stage of FIG. 10D is still valid.

FIG. 10D illustrates a side view of the dicing stage. FIG. 10E illustrates a top view of the substrates 230 with the dicing boundaries 860 (mold 250 not shown). It is easy to visualize that after the dicing, the die packages similar to the die packages 410 illustrated FIGS. 5A and 5B (top view illustrations) are formed. In FIG. 10E, the plurality of second contacts 445 are shown to be circular to indicate that Cu plating process may be utilized.

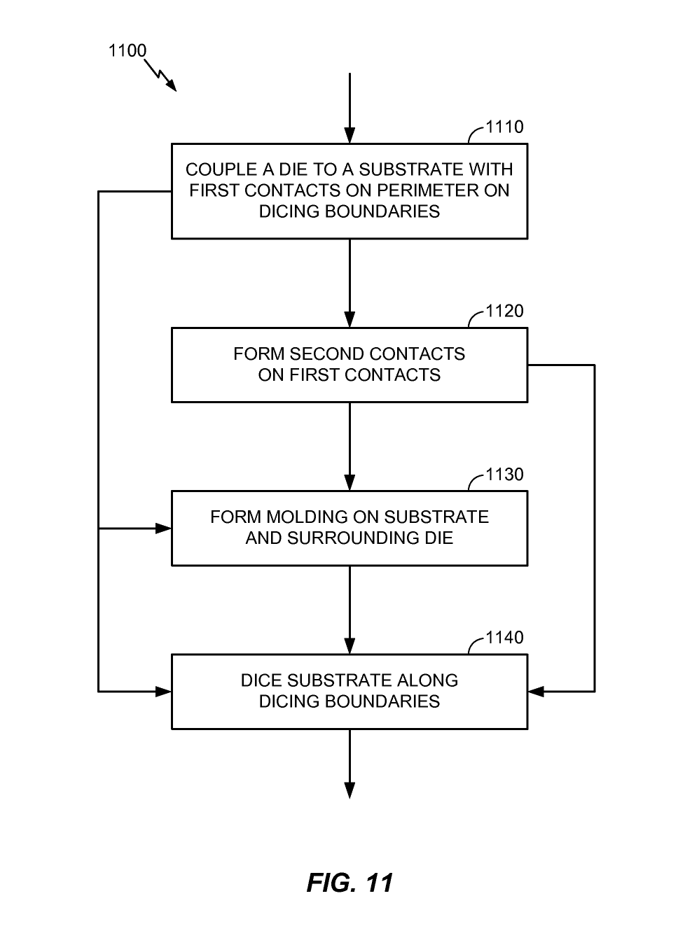

FIG. 11 illustrates a flow chart of an example method 1100 to form a die package 210, 410. The method 1100 includes attaching a die 220 on a substrate 230 (block 1110). The substrate 230 is one of a plurality of substrates 230 with dicing boundaries 860. In an aspect, this block corresponds to stages illustrated in FIGS. 8A, 9A and 10B. A plurality of first contacts 240 are formed on the dicing boundaries 860 on an outer perimeter of the substrate 230.

The method 1100 also includes dicing the plurality of substrates 230 along the dicing boundaries 860 (block 1140). In an aspect, block corresponds to stages illustrated in FIGS. 8C, 9D and 10D. When the plurality of substrates 230 are diced, the substrates 230 are separated from each other. The plurality of first contacts 240 are diced as well. In an aspect, performing blocks 1110 and 1140 produce the die package 210 of FIG. 2A without the mold 250.

The method 1100 may further include forming a mold 250 on the substrates 230 (block 1130). In an aspect, this block corresponds to stages illustrated in FIGS. 8B, 9C and 10C, and may be performed prior to block 1140 of dicing the plurality of substrates 230. The mold 250 at least partially surrounds the die 220 above the substrate 230. When block 1140 of dicing the substrates 230 is performed, the mold 250 is also diced. In an aspect, performing blocks 1110, 1130 and 1140 produce the die package 210 of FIG. 2A with the mold 250.

The method 1100 may additionally include forming a plurality of second contacts 445 (block 1120). In an aspect, this block corresponds to stages illustrated in FIGS. 9B and 10A, and is performed prior to block 1140 of dicing the substrates 230. While not shown, in an aspect, this block may also be performed prior to block 1110 of attaching the die 220 to the substrate 230. The plurality of second contacts 445 are disposed around the die 220 and formed so as to be electrically coupled to the plurality of first contacts 240.

The plurality of second contacts 445 may be formed in various ways. In one aspect, the plurality of second contacts 445 are formed through a surface mount process with reflow. That is, the plurality of second contacts 445 are surface mounted on the plurality of first contacts 240. In another aspect, the plurality of second contacts 445 are formed through a conductive post plating process. For example, Cu posts may be formed on the plurality of first contacts 240.

When block 1140 of dicing the substrates 230 is performed, the plurality of second contacts 445 are be diced. In an aspect, performing blocks 1110, 1120 and 1140 produce the die package 410 of FIG. 4 without the mold 250. However, block 1130 of forming the mold 250 may also be performed. That is, in an aspect, performing blocks 1110, 1120, 1130 and 1140 produce the die package 410 of FIG. 4 with the mold 250.

Those of skill in the art will appreciate that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Further, those of skill in the art will appreciate that the various illustrative logical blocks, modules, circuits, and algorithms described in connection with the implementations disclosed herein may be implemented as electronic hardware, computer software, or combinations of both. To clearly illustrate this interchangeability of hardware and software, various illustrative components, blocks, modules, circuits, and processes have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present technology described herein.

The methods, sequences, and/or algorithms described in connection with the implementations disclosed herein may be embodied directly in hardware, in a software module executed by a processor, or in a combination of the two. A software module may reside in RAM memory, flash memory, ROM memory, EPROM memory, EEPROM memory, registers, hard disk, a removable disk, a CD-ROM, or any other form of storage medium known in the art. An exemplary storage medium is coupled to the processor such that the processor can read information from, and write information to, the storage medium. In the alternative, the storage medium may be integral to the processor.

Accordingly, an implementation of the technology described herein can include a computer-readable media embodying a method of manufacturing a semiconductor device. Accordingly, the technology described herein is not limited to illustrated examples, and any means for performing the functionality described herein are included in implementations of the technology described herein.

While the foregoing disclosure shows illustrative implementations of the technology described herein, it should be noted that various changes and modifications could be made herein without departing from the scope of the technology described herein as defined by the appended claims. The functions and/or actions of the method claims in accordance with the implementations of the technology described herein described herein need not be performed in any particular order. Furthermore, although elements of the technology described herein may be described or claimed in the singular, the plural is contemplated unless limitation to the singular is explicitly stated.

What is claimed is:

1. A die package, comprising:
a die coupled to a substrate; and
a plurality of package contacts on an outer perimeter of the die package, the plurality of package contacts configured to mate with a connector,
the die configured to electrically couple to the connector through the plurality of package contacts and through a plurality of connector contacts if the plurality of package contacts are mated with the plurality of connector contacts.

2. The die package of claim 1, the plurality of package contacts comprising:
a plurality of first contacts on an outer perimeter of the substrate and configured to electrically couple to the die through the substrate, the plurality of first contacts configured to mate with the plurality of connector contacts.

3. The die package of claim 1, the plurality of package contacts comprising:
a plurality of first contacts on an outer perimeter of the substrate and configured to electrically couple to the die through the substrate; and
a plurality of second contacts around the die and configured to electrically couple to the plurality of first contacts, the plurality of second contacts configured to mate with the plurality of connector contacts.

4. The die package of claim 3, the plurality of first contacts also configured to mate with the plurality of connector contacts.

5. The die package of claim 3, further comprising:
a plurality of intermediate contacts configured to provide electrical connectivity between the plurality of first contacts and the plurality of second contacts.

6. The die package of claim 5, the plurality of intermediate contacts are directly over the plurality of first contacts, and
the plurality of second contacts are directly over the plurality of intermediate contacts.

7. The die package of claim 6, the plurality of intermediate contacts comprise a plurality of solder contacts.

8. The die package of claim 3, the plurality of second contacts are such that less than all of the plurality of first contacts are electrically coupled to the plurality of second contacts.

9. The die package of claim 8, the plurality of first contacts are such that at least one first contact is electrically coupled to a corresponding connector contact and is not electrically coupled to any second contact.

10. The die package of claim 3, further comprising:
a mold over the substrate and at least partially surrounding the die, the plurality of second contacts on an outer perimeter of the mold.

11. The die package of claim 1, the plurality of package contacts configured such that sides of the plurality of package contacts mate with the plurality of connector contacts.

12. The die package of claim 1, the substrate is mounted on a mounting board.

13. The die package of claim 12, the die configured to electrically couple to the connector other than through the mounting board.

14. The die package of claim 12, the connector configured to be removable and separate from the mounting board.

15. The die package of claim 12, the mounting board comprising a printed circuit board (PCB).

16. A method of forming a die package, the method comprising:
coupling a die to a substrate; and
forming a plurality of package contacts on an outer perimeter of the die package for mating with a connector, the plurality of package contacts for electrically coupling to the connector through a plurality of connector contacts if the plurality of package contacts are mated with the plurality of connector contacts.

17. The method of claim 16, the forming the plurality of package contacts comprising:
forming a plurality of first contacts on an outer perimeter of the substrate for electrically coupling to the die through the substrate, and for mating with the plurality of connector contacts.

18. The method of claim 16, the forming the plurality of package contacts comprising:
forming a plurality of first contacts on an outer perimeter of the substrate for electrically coupling the die through the substrate; and
forming a plurality of second contacts around the die for electrically coupling to the plurality of first contacts, and for mating with the plurality of connector contacts.

19. The method of claim 18, the forming the plurality of package contacts further comprising:
forming the plurality of first contacts also for mating with the plurality of connector contacts.

20. The method of claim 18, forming the plurality of package contacts further comprising:
forming the plurality of first contacts and/or the plurality of second contacts such that less than all of the plurality of first contacts are electrically coupled to the plurality of second contacts.

21. The method of claim 16, further comprising:
mounting the substrate on a mounting board without electrically coupling the die through the mounting board.

22. The method of claim 16, the coupling the die to the substrate and the forming the plurality of package contacts comprising:
attaching the die on a substrate, the substrate being one of a plurality of substrates and comprising the plurality of first contacts formed on a dicing boundary on an outer perimeter the substrate, the die electrically coupled to the plurality of first contacts through the substrate; and
dicing the plurality of substrates along the dicing boundary for separating the substrate from other substrates, the dicing also dicing the plurality of first contacts for mating with the plurality of connector contacts.

23. The method of claim 22, further comprising:
forming a plurality of second contacts around the die for electrically coupling to the plurality of first contacts, the dicing also dicing the plurality of second contacts for mating with the plurality of connector contacts.

24. The method of claim 22, further comprising:
forming a mold above the substrate for at least partially surrounding the die, the dicing also dicing the mold.
